(19) United States
(12) Patent Application Publication
(10) Pub. No.: US 2026/0182260 A1
(43) Pub. Date: Jun. 25, 2026

(54) MEMORY CELL AND METHOD OF FORMING THE SAME

(71) Applicant: Taiwan Semiconductor Manufacturing Company, Ltd., Hsinchu (TW)

(72) Inventors: Kuo-Pin Chang, Zhubei City (TW); Ching-En Chen, Chiayi City (TW); Hung-Ju Li, Hsinchu City (TW); Yu-Wei Ting, Taipei City (TW); Kuo-Ching Huang, Hsinchu City (TW)

(73) Assignee: Taiwan Semiconductor Manufacturing Company, Ltd., Hsinchu (TW)

(21) Appl. No.: 19/001,532

(22) Filed: Dec. 25, 2024

(51) Int. Cl. H10N 70/00; H10B 63/10; H10N 70/20

(52) U.S. Cl. CPC H10N 70/8265; H10B 63/10; H10N 70/063; H10N 70/231

(57) ABSTRACT

A memory cell including a first electrode, a second electrode, a storage element layer and a liner layer is provided. The storage element layer is disposed between the first electrode and the second electrode. The liner layer covers the first electrode, the storage element layer and the second electrode. The liner layer includes a first liner portion and at least one second liner portion, wherein the first liner portion is disposed between the first electrode and the storage element layer, at least one second liner portion covers at least one sidewall of the first electrode, at least one sidewall of the storage element layer and at least one sidewall of the second electrode, and the at least one second liner portion is connected to the first liner portion.

### BACKGROUND

Flash memory is a widely used type of nonvolatile memory. However, flash memory is expected to encounter scaling difficulties. Therefore, alternatives types of nonvolatile memory are being explored. Among these alternatives types of nonvolatile memory is phase change memory (PCM). PCM is a type of nonvolatile memory in which a phase of a PCM is employed to represent a unit of data. PCM has fast read and write times, non-destructive reads, and high scalability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 6 schematically illustrate cross-sectional views of fabricating process of a memory cell in accordance with some embodiments of the present disclosure.

FIG. 7 schematically illustrates a top view of the film stacks illustrated in FIG. 2.

FIG. 8 schematically illustrates a top view of the film stacks and the second liner portion illustrated in FIG. 4.

FIG. 9 through FIG. 11 schematically illustrate cross-sectional views of various memory cells in accordance with some alternative embodiments of the present disclosure.

FIG. 12 through FIG. 17 schematically illustrate cross-sectional views of fabricating process of a memory cell in accordance with some other embodiments of the present disclosure.

FIG. 18 schematically illustrates a top view of the film stacks illustrated in FIG. 13 in accordance with some embodiments of the present disclosure.

FIG. 19 schematically illustrates a top view of the film stacks and the liner spacers illustrated in FIG. 15 in accordance with some embodiments of the present disclosure.

FIG. 20 schematically illustrates a top view of the film stacks and the second liner portions illustrated in FIG. 16 in accordance with some embodiments of the present disclosure.

FIG. 21 schematically illustrates a top view of the memory cell illustrated in FIG. 13 in accordance with some alternative embodiments of the present disclosure.

FIG. 22 schematically illustrates a top view of the memory cell illustrated in FIG. 15 in accordance with some alternative embodiments of the present disclosure.

FIG. 23 schematically illustrates a top view of the memory cell illustrated in FIG. 16 in accordance with some alternative embodiments of the present disclosure.

FIG. 24 through FIG. 26 schematically illustrates top views of the memory cell in accordance with some other embodiments of the present disclosure.

FIG. 27 schematically illustrates various states of the memory cell in accordance with some other embodiments of the present disclosure.

FIG. 28 schematically illustrates a perspective view of a memory cell array in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Computing-In-Memory (CIM) application is applied in artificial intelligence (AI) field. Currently, PCM is utilized in emerging memory for CIM application, and PCM faces some challenges in reliability (e.g., endurance, retention, read disturb, and/or stability issues), Multi-Level Coding (MLC) capability (e.g., linear conductance and/or tight distribution issues), and/or write voltage compatible to advance node. The novel design for liner layer in PCM may minimize the resistance drift issue resulted from structure relaxation of phase change material as well as avoid weight error in CIM computing due to the resistance drift issue. The novel design for liner layer in PCM may stabilize the high resistance state (HRS) resistivity and the low resistance state (LRS) resistivity of PCM. The novel design for liner layer in PCM may enhance the MLC capability of PCM. Furthermore, the novel design for liner layer in PCM may effectively reduce operation power of PCM and layout area for fabricating the PCM, as well as provide accuracy weight for CIM computing.

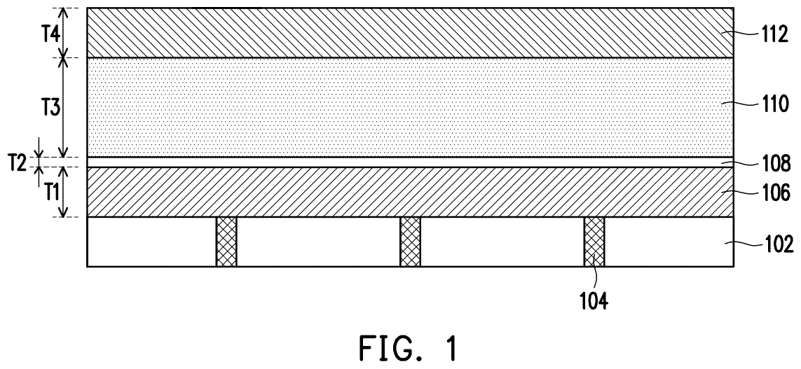

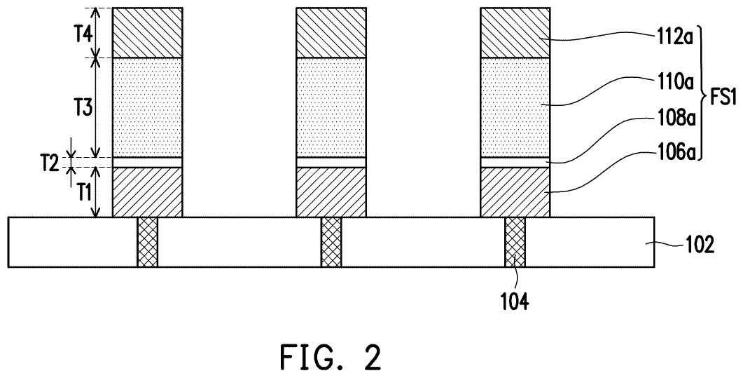

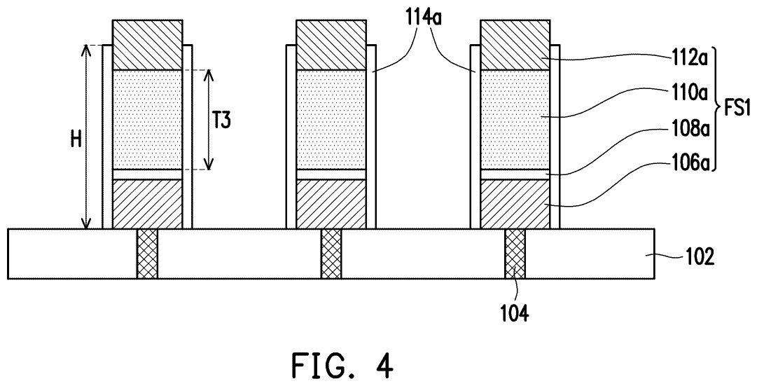

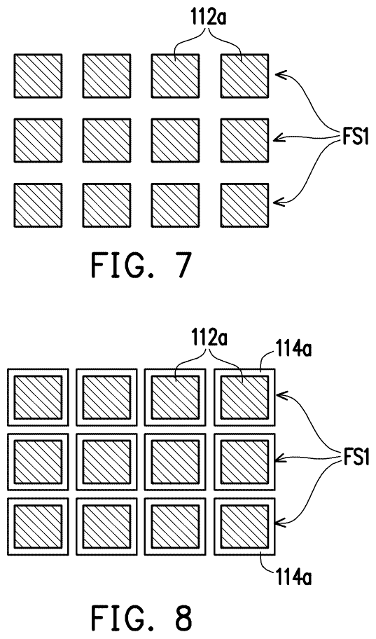

FIG. 1 through FIG. 6 schematically illustrate cross-sectional views of fabricating process of a memory cell in accordance with some embodiments of the present disclosure. FIG. 7 schematically illustrates a top view of the film stacks illustrated in FIG. 2. FIG. 8 schematically illustrates a top view of the film stacks and the second liner portion illustrated in FIG. 4. The memory cell illustrated in the following embodiments may be applied to, but not limited thereto, a phase change random access memory (PCRAM) cell, hereinafter referred to as a PCM cell.

Referring to FIG. 1, a dielectric layer 102 including conductive vias 104 embedded in the dielectric layer 102 is formed. The first dielectric layer 102 may include a dielectric material, such as silicon oxide, silicon nitride, silicon oxynitride, a spin-on dielectric material, or a low-k dielectric material. It should be noted that the low-k dielectric materials are generally dielectric materials having a dielectric constant lower than 3.9. The first dielectric layer 102 may be formed by any suitable method, such as chemical vapor deposition (CVD), or the like. The conductive vias 104 may be formed by a damascene process (e.g., a single damascene process). For example, openings are formed in the first dielectric layer 102 through photolithography and etch process, and the openings in the first dielectric layer 102 are filled with a conductive material. In a subsequent step, a planarization process (e.g., a chemical-mechanical planarization (CMP) process) is performed to remove excessive conductive material, thereby forming the conductive vias 104. The conductive vias 104 may be formed by conductive material, such as Ti, Co, Cu, AlCu, W, WN, TiC, TiN, TiW, TiAl, TiAlN, Ru, RuOₓ, or a combination thereof.

A first conductive layer 106, a first liner material layer 108, a storage element material layer 110, and a second conductive layer 112 are sequentially formed over the first dielectric layer 102 and the conductive vias 104. The first conductive layer 106, the first liner material layer 108, the storage element material layer 110, and the second conductive layer 112 may be formed by any suitable method, such as chemical vapor deposition (CVD), atomic layer deposition (ALD), or the like. The first conductive layer 106 may be formed by conductive material, such as Ti, Co, Cu, AlCu, W, WN, TiC, TiN, TiW, TiAl, TiAlN, Ru, RuOₓ, or a combination thereof. The material of the first conductive layer 106 may be identical to or different from the material of the conductive vias 104. The thickness T1 of the first conductive layer 106 may range from about 300 angstroms to about 900 angstroms. The first liner material layer 108 may be formed by TiN, TaN, C-doped TaN, C-doped TiN, N-rich WN, N-rich Ta, or N-rich TiN. The thickness T2 of the first liner material layer 108 may range from about 10 angstroms to about 200 angstroms.

The storage element material layer 110 is on the first liner material layer 108. The storage element material 110 may be a phase change material. The phase change material may include a chalcogenide material, such as an indium(In)-antimony(Sb)-tellurium(Te) (IST) material or a germanium(Ge)-antimony(Sb)-tellurium(Te) (GST) material. The ISG material may include In₂Sb₂Te₅, In₁Sb₂Te₄, In₁Sb₄Te₇, or the like. The GST material may include Ge₈Sb₅Te₈, Ge₂Sb₂Te₅, Ge₁Sb₂Te₄, Ge₁Sb₄Te₇, Ge₄Sb₄Te₇, Ge₄SbTe₂, Ge₆SbTe₂, or the like. The hyphenated chemical composition notation, as used herein, indicates the elements included in a particular mixture or compound, and is intended to represent all stoichiometries involving the indicated elements. Other phase change materials may include Ge—Te, In—Se, Sb—Te, Ga—Sb, In—Sb, As—Te, Al—Te, Ge—Sb—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt, for example. Other storage element materials include transition metal oxide materials or alloys including two or more metals, such as transition metals, alkaline earth metals, and/or rare earth metals. Furthermore, the thickness T3 of the storage element material layer 110 may range from about 300 angstroms to about 2000 angstroms.

The second conductive layer 112 may be formed by conductive material, such as Ti, Co, Cu, AlCu, W, WN, TiC, TiN, TiW, TiAl, TiAlN, Ru, RuOₓ, or a combination thereof. The material of the second conductive layer 112 may be identical to or different from the material of the first conductive layer 106 and the conductive vias 104. Furthermore, the thickness T4 of the second conductive layer 112 may range from about 600 angstroms to about 1800 angstroms.

Referring to FIG. 1, FIG. 2 and FIG. 7, a patterning process (e.g., a photolithography process followed by an etch process) is performed to pattern the first conductive layer 106, the first liner material layer 108, the storage element material layer 110 and the second conductive layer 112 to form film stacks FS1, and each of the film stacks FS1 may respectively include a first electrode 106a, a first liner portion 108a on the first electrode 106a, a storage element layer 110a on the first liner portion 108a, and a second electrode 112a on the storage element layer 110a. The film stacks FS1 lands on the first dielectric layer 102 and are electrically connected to one of the underlying conductive vias 104. The film stacks FS1 are arranged in array and spaced apart from each other, as illustrated in FIG. 7.

In some embodiments, the conductive vias 104 and the first electrodes 106a are referred to as heaters that are coupled to the overlying structures (e.g., the storage element layers 110a) and the underlying structures (e.g., bit lines, write driver transistors, and/or selectors).

The thickness T2 of the first liner portions 108a may range from about 10 angstroms to about 200 angstroms. The thickness T3 of the storage element layers 110a may range from about 300 angstroms to about 2000 angstroms. The storage element layers 110a (e.g., the phase change material) may switch between a low resistance state (LRS) and a high resistance state (HRL), the storage element layers 110a (e.g., the phase change material) has a first resistivity Rc when the storage element layers 110a (e.g., the phase change material) switches to the low resistance state (LRS), and the storage element layers 110a (e.g., the phase change material) has a second resistivity Ra when the storage element layers 110a (e.g., the phase change material) switches to the high resistance state (HRS). For example, when the storage element layers 110a (e.g., the phase change material) switches to the low resistance state (LRS), the storage element layers 110a (e.g., the phase change material) switches to crystalline phase; and when the storage element layers 110a (e.g., the phase change material) switches to the high resistance state (HRS), a portion of the storage element layers 110a (e.g., the phase change material) switches to amorphous phase while the rest portion of the storage element layers 110a (e.g., the phase change material) remains crystalline phase.

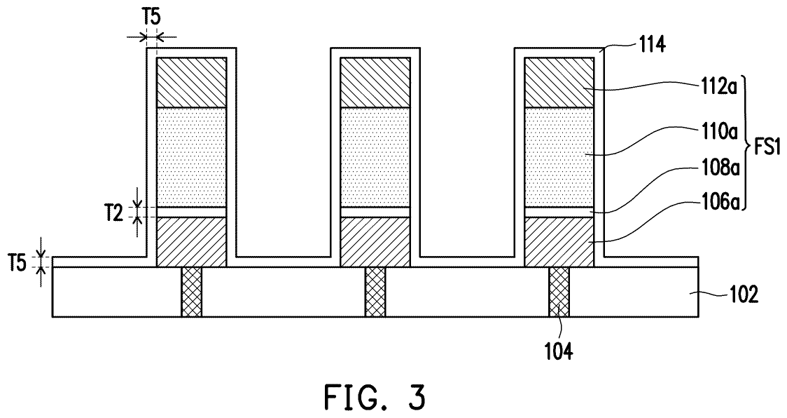

Referring to FIG. 3, a second liner material layer 114 is formed to conformally cover the film stacks FS1 and the revealed top surface of the first dielectric layer 102. The second liner material layer 114 may cover the top surfaces and sidewalls of the film stacks FS1. In other words, the second liner material layer 114 may cover top surfaces of the second electrodes 112a, sidewalls of the second electrodes 112a, sidewalls of the storage element layers 110a, sidewalls of the first liner portions 108a and sidewalls of the first electrodes 106a. The second liner material layer 114 may be formed by any suitable method, such as chemical vapor deposition (CVD), or the like. The second liner material layer 114 may be formed by TiN, TaN, C-doped TaN, C-doped TiN, N-rich WN, N-rich Ta, or N-rich TiN. The material of the first liner portions 108a may be identical to or different from the material of the second liner material layer 114. The thickness T5 of the second liner material layer 114 may range from about 10 angstroms to about 200 angstroms. In some embodiments, the thickness T5 of the second liner material layer 114 may be identical to the thickness T2 of the first liner portions 108a. In some other embodiments, the thickness T5 of the second liner material layer 114 may be different from the thickness T2 of the first liner portions 108a.

Referring to FIG. 3, FIG. 4 and FIG. 8, a removal process is performed to remove portions of the second liner material layer 114 to form second liner portions 114a (i.e. sidewall liner portions). In the present embodiment, the second liner portions 114a include liner spacers surrounding the film stacks FS1, as illustrated in FIG. 8. After performing the removal process, the portions of the second liner material layer 114 which cover the top surfaces, upper portions of sidewalls of the second electrodes 112a and the revealed top surface of the first dielectric layer 102 are removed. The second liner portions 114a covers lower portions of the sidewalls of the second electrode, the sidewalls of the storage element layers 110a, the sidewalls of the first liner portions 108a and the sidewalls of the first electrodes 106a. The bottom ends of the second liner portions 114a are in contact with the top surface of the first dielectric layer 102.

As illustrated in FIG. 4, the second electrodes 112a are revealed after removing the portion of the second liner material layer 114 on the top surfaces of the film stacks FS1. For example, the top surfaces of the second electrodes 112a and the upper portions of the sidewalls of the second electrodes 112a are revealed. In some embodiments, the resistivity R3 of the second liner portions 114a is equal to the resistivity R1 of the first liner portions 108a. In some alternative embodiments, the resistivity R3 of the second liner portions 114a is different from the resistivity R1 of the first liner portions 108a.

As illustrated in FIG. 4, the height H of the second liner portions 114a is greater than the thickness T3 of the storage element layers 110a. The height H of the second liner portions 114a is greater than the sum (T3+T2+T1) of the thickness T3 of the storage element layers 110a, the thickness T2 of the first liner portions 108a and the thickness T1 of the first electrodes 106a. Furthermore, in some embodiments, the height H of the second liner portions 114a is less than the sum (T4+T3+T2+T1) of the thickness T4 of the second electrodes 112a, the thickness T3 of the storage element layers 110a, the thickness T2 of the first liner portions 108a and the thickness T1 of the first electrodes 106a.

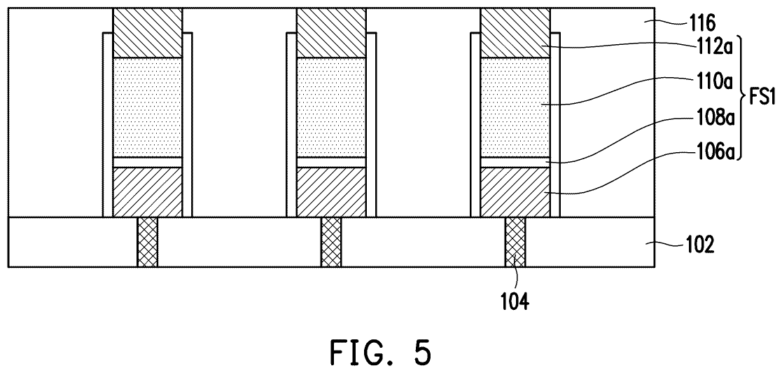

Referring to FIG. 5, after forming the second liner portions 114a, a dielectric layer 116 is formed on the dielectric layer 102 to cover the film stacks FS1 and the second liner portions 114a. In some embodiments, the dielectric layer 116 is formed on the dielectric layer 102 to laterally encapsulate film stacks FS1 and the second liner portions 114a. In some embodiments, the dielectric layer 116 is formed by any suitable method, such as chemical vapor deposition (CVD), or the like. In a subsequent step, a planarization process (e.g., a chemical-mechanical planarization (CMP) process) is performed to remove excessive dielectric material, thereby forming the dielectric layer 116. The top surface of the dielectric layer 116 may substantially level with the top surfaces of the film stacks FS1. In other words, the top surface of the dielectric layer 116 may substantially level with the top surfaces of the second electrodes 112a. Furthermore, the top ends of the second liner portions 114a are lower than the top surface of the dielectric layer 116. In some embodiments, the dielectric layer 116 is referred to as an inter-metal dielectric (IMD) layer which includes a dielectric material, such as silicon oxide, silicon nitride, silicon oxynitride, a spin-on dielectric material, or a low-k dielectric material. It should be noted that the low-k dielectric materials are generally dielectric materials having a dielectric constant lower than 3.9.

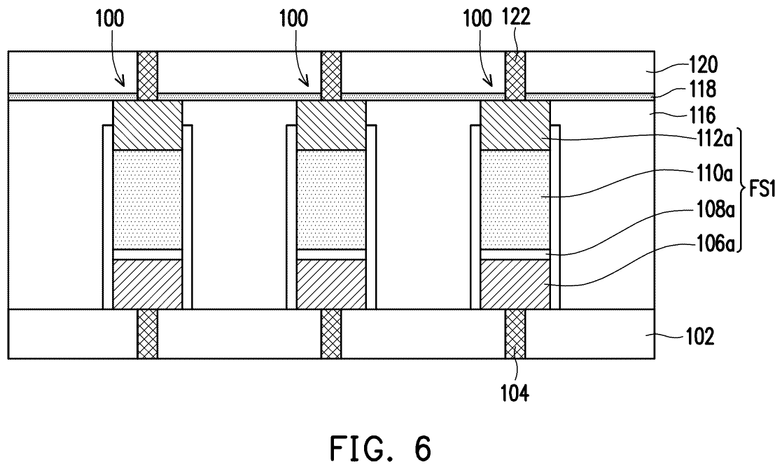

Referring to FIG. 6, after forming the dielectric layer 116, an etch-stop layer 118 and a dielectric layer 120 are sequentially formed over the dielectric layer 116 and the second electrodes 112a. The etch-stop layer 118 is formed on the dielectric layer 116, and the dielectric layer 120 is formed on the etch-stop layer 118. The etch-stop layer 118 is in contact with the second electrodes 112a and the dielectric layer 116. In some embodiments, the etch-stop layer 118 includes SiC, SiN, SiON, HfOₓ, ZrOₓ, LaOₓ, or a combination thereof. The etch-stop layer 118 may be formed by any suitable method, such as chemical vapor deposition (CVD), or the like. In some embodiments, the dielectric layer 120 may be made of a dielectric material, such as silicon oxide, silicon nitride, silicon oxynitride, a spin-on dielectric material, or a low-k dielectric material. The dielectric layer 120 may be formed by any suitable method, such as chemical vapor deposition (CVD), or the like.

In some embodiments, portions of the dielectric layer 120 and portions of the etch-stop layer 118 are removed to form second openings (not shown) revealing the top surfaces of the second electrodes 112a. In some embodiments, portions of the dielectric layer 120 and portions of the etch-stop layer 118 are removed by etching process. In certain embodiments, the etch-stop layer 118 is used to prevent the underlying layers from damage caused by the over-etching of the dielectric layer 120. In a subsequent step, conductive vias 122 are formed in the second openings defined in the dielectric layer 120 and the etch-stop layer 118, wherein the conductive vias 122 are electrically connected to the second electrodes 112a. In some embodiments, the conductive vias 122 are formed by a damascene process (e.g., a single damascene process). For example, after forming the second openings, a conductive material is formed to fill into the second openings. Thereafter, a planarization process (e.g., a CMP process) is performed to remove excessive conductive material, thereby forming the conductive vias 122. In some embodiments, the conductive vias 122 includes metals or metal alloys including one or more of Al, AlCu, Cu, Ti, TiN, W, or the like. In some embodiments, the conductive vias 122 and the second electrodes 112a are electrically connected to the overlying structures (e.g., word lines).

As illustrated in FIG. 6, memory cells 100 are essentially accomplished after forming the conductive vias 122. In some embodiments, each one of the memory cells 100 respectively includes the first electrode 106a, a second electrode 112a, a storage element layer (e.g., a phase change material) 110a and a liner layer having the first liner portions 108a and the second liner portions 114a. In each one of the film stacks FS1, the storage element layer 110a is disposed between the first electrode 106a and the second electrode 112a. The second liner portions 114a of liner layer covers the first electrode 106a, the storage element layer 110a and the second electrode 112a. The first liner portion 108a of the liner layer is disposed between the first electrode 106a and the storage element layer 110a, at least one second liner portion 114a of the liner layer covers at least one sidewall of the first electrode 106a, at least one sidewall of the storage element layer 110a and at least one sidewall of the second electrode 112a, and the at least one second liner portion 114a is connected to the first liner portion 108a.

The storage element layer (e.g., a phase change material) 110a has a crystalline phase and an amorphous phase which are interchangeable. The crystalline phase and the amorphous phase may respectively represent a binary “1” and a binary “0”, or vice versa. Accordingly, the storage element layer (e.g., a phase change material) 110a has a variable resistance that changes with the variable phase of the storage element layer (e.g., a phase change material) 110a. For example, the storage element layer (e.g., a phase change material) 110a has a high resistance in the amorphous phase and a low resistance in the crystalline phase. According to some embodiments, in the memory cell 100, the data state of the memory cell 100 is read by measuring the resistance of the memory cell 110 (i.e., the resistance from the first electrode 106a to the second electrode 112a). The phase of the storage element layer (e.g., a phase change material) 110a represents the data state of the memory cell 100, the resistance of the storage element layer (e.g., a phase change material) 110a, or the resistance of the memory cell 100. Furthermore, the data state of the memory cell 100 may be set and reset by changing the phase of the storage element layer (e.g., a phase change material) 110a.

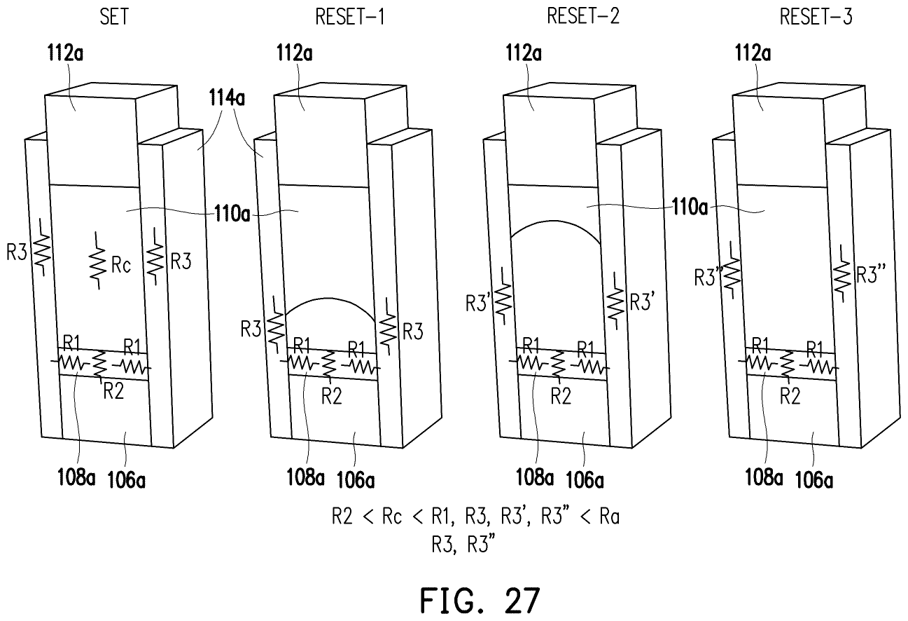

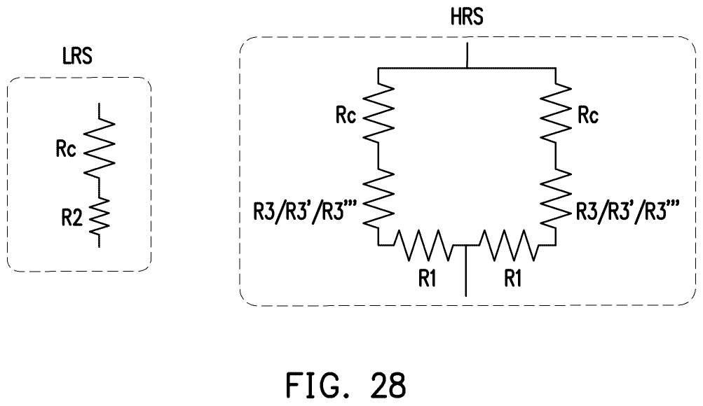

In some embodiments, the phase of the storage element layer (e.g., a phase change material) 110a is changed by heating. For example, the first electrode 106a heats the storage element layer (e.g., a phase change material) 110a to a first temperature that induces crystallization of the storage element layer (e.g., a phase change material) 110a, so as to change the storage element layer (e.g., a phase change material) 110a to the crystalline phase (e.g., to set the memory cell 100). The above-mentioned procedure is so-called “SET” procedure of PCM, as illustrated in FIG. 27. As illustrated in FIG. 27 and FIG. 28, a “SET” procedures may be may be achieved by heating the storage element layer (e.g., a phase change material) 110a to the first temperature such that the memory cell 100 can be set to a low resistance state (LRS). The circuit diagram of the memory cell 100 in LRS is illustrated in FIG. 28. Similarly, the first electrode 106a heats the storage element layer (e.g., a phase change material) 110a to a second temperature that melts the storage element layer (e.g., a phase change material) 110a, so as to change the storage element layer (e.g., a phase change material) 110a to the amorphous phase (e.g., to reset the memory cell 100). The first temperature is lower than the second temperature. In some embodiments, the first temperature is about 100° C. to about 200° C. and the second temperature is about 500° C. to about 800° C. The above-mentioned procedure is so-called “RESET” procedure of PCM. As illustrated in FIG. 27, various “RESET” procedures (e.g., “RESET-1”, “RESET-2” and “RESER-3” procedures) may be performed in the memory cell 100. Various “RESET” procedures (e.g., “RESET-1”, “RESET-2” and “RESER-3” procedures) may be achieved by heating the storage element layer (e.g., a phase change material) 110a to different second temperature such that the memory cell 100 can be reset to various high resistance states (HRS). Accordingly, the memory cell 100 may have MLC capability. The circuit diagrams of the memory cell 100 in various HRS are illustrated in FIG. 28. In FIG. 27 and FIG. 28, the first liner portion 108a has resistivity R1 in horizontal direction and resistivity R2 in vertical direction, wherein the resistivity R1 is greater than the resistivity R2. In LRS of the memory cell, the storage element layer (e.g., a phase change material) 110a has resistivity Rc. In HRS of the memory cell, the second liner portions 114a have resistivities R3, R3′ or R3″, crystalline portions of the storage element layers (e.g., a phase change material) 110a have resistivity Rc, amorphous portions of the storage element layers (e.g., a phase change material) 110a have resistivity Ra, and the resistivities R3, R3′ or R3″ of the second liner portions 114a dominate the overall resistivity of the memory cells, wherein R2<Rc<R1, R3, R3′, R3″<Ra. Accordingly, the resistance drift issue of PCM can be solved. For example, the resistivity R1 of the first liner portions 108a may range from about 0.001 Ω·m to about 0.1 Ω·m, the resistivity R2 of the first liner portions 108a may range from about 0.001 Ω·m to about 0.1 Ω·m. The resistivities R3, R3′ and R3″ of the second liner portions 114a may range from about 0.001 Ω·m to about 0.1 Ω·m. The resistivity Rc may range from about 0.001 Ω·m to about 0.1 Ω·m. The resistivity Ra may range from about 1E2 Ω·m to about 1E5 Ω·m.

The amount of heat generated by the first electrode 106a varies in proportion to the current applied to the first electrode 106a. That is, the storage element layer (e.g., a phase change material) 110a is heated up to a temperature (i.e., the second temperature) higher than the melting temperature when a current passes through. The temperature is then quickly dropped below the crystallization temperature. In this case, a portion of the storage element layer (e.g., a phase change material) 110a contacting the first electrode 106a is changed to the amorphous state with high resistivity, and thus the state of the storage element layer (e.g., a phase change material) 110a is changed to a high resistance state (HRS). Then, the portion of the storage element layer (e.g., a phase change material) 110a may be reset back to the crystalline state by heating up the storage element layer (e.g., a phase change material) 110a to a temperature (i.e., the first temperature) higher than the crystallization temperature and lower than the melting temperature, for a certain period.

Based on the above, it is known that the storage element layer (e.g., a phase change material) 110a is a key layer for operating the memory cell 100. In the present embodiment, the liner layer including the first liner portion 108a and the second liner portions 114a may minimize the resistance drift issue resulted from structure relaxation of the storage element layer (e.g., a phase change material) 110a as well as avoid weight error in CIM computing due to the resistance drift issue. Furthermore, the liner layer including the first liner portion 108a and the second liner portions 114a may stabilize the high resistance state (HRS) resistivity and the low resistance state (LRS) resistivity of the memory cell 100.

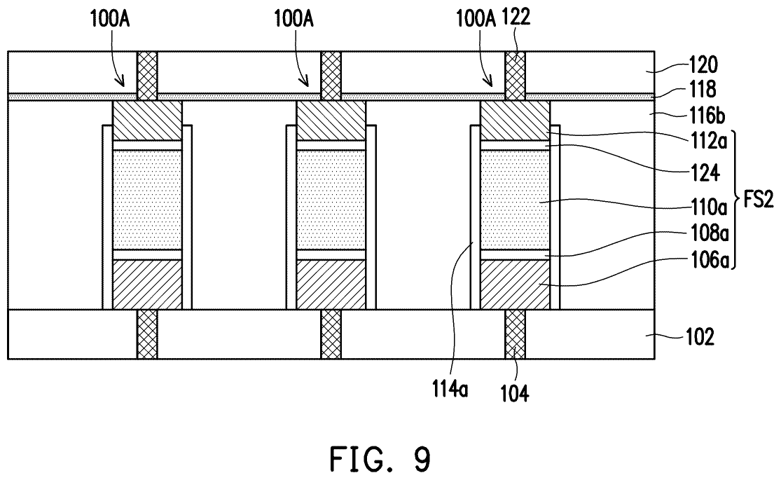

FIG. 9 through FIG. 11 schematically illustrate cross-sectional views of various memory cells in accordance with some alternative embodiments of the present disclosure.

Referring to FIG. 6 and FIG. 9, the memory cell 100A illustrated in FIG. 9 in similar to the memory cell 100 illustrated in FIG. 6 except that the film stacks FS2 of the memory cell 100A further include third liner portions 124 disposed between the storage element layers (e.g., a phase change material) 110a and the second electrodes 112a. The thickness and the resistivity of the third liner portions 124 may be similar to those of the first liner portions 108a. Accordingly, the detailed descriptions of the third liner portions 124 are omitted. In some alternative embodiments, not shown in figures, the first liner portions 108a may be omitted while the third liner portions 124 is formed between the storage element layers (e.g., a phase change material) 110a and the second electrodes 112a.

Referring to FIG. 9 and FIG. 10, the memory cell 100B illustrated in FIG. 10 in similar to the memory cell 100A illustrated in FIG. 9 except that the first electrodes 106a of the film stacks FS2 are embedded in a dielectric layer 116a, the bottom ends of the second liner portions 114a lands on and are in contact with the dielectric layer 116a, and the second liner portions 114a does not cover the sidewalls of the first electrodes 106a. Furthermore, the second liner portions 114a are embedded in a dielectric layer 116b, and the second liner portions 114a merely covers the sidewalls of the first liner portions 108a, the sidewalls of the storage element layers (e.g., a phase change material) 110a, the sidewalls of the third liner portion 124 and the sidewalls of the second electrodes 112a.

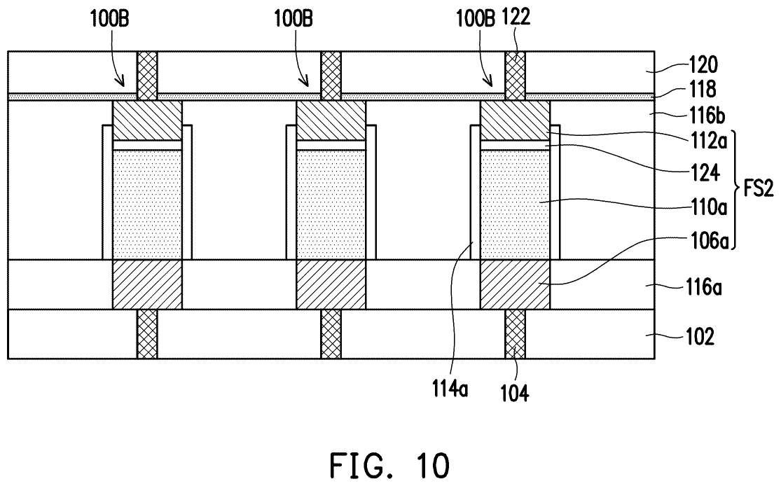

Referring to FIG. 10 and FIG. 11, the memory cell 100C illustrated in FIG. 11 in similar to the memory cell 100B illustrated in FIG. 10 except that the film stacks FS3 does not include the first liner portions 108a formed between the storage element layers (e.g., a phase change material) 110a and the first electrodes 106a. Furthermore, the second liner portions 114a merely covers the sidewalls of the storage element layers (e.g., a phase change material) 110a, the sidewalls of the third liner portion 124 and the sidewalls of the second electrodes 112a.

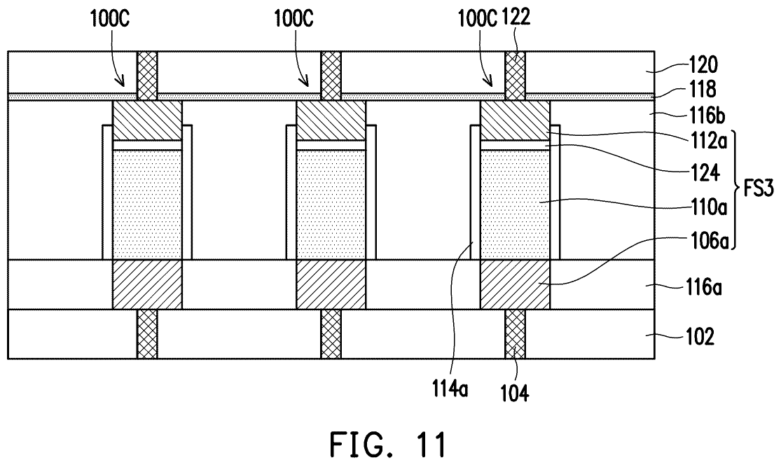

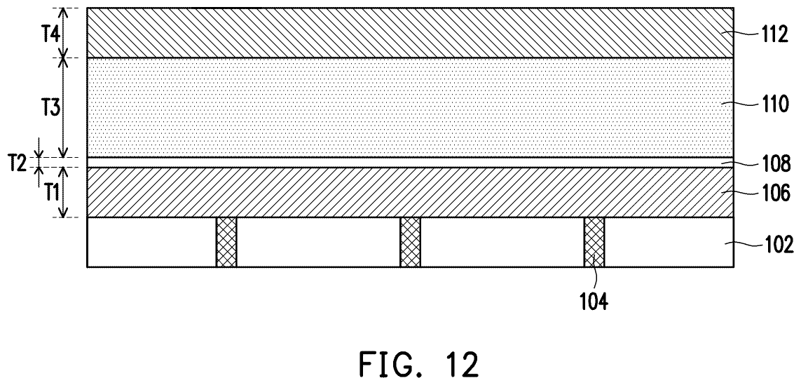

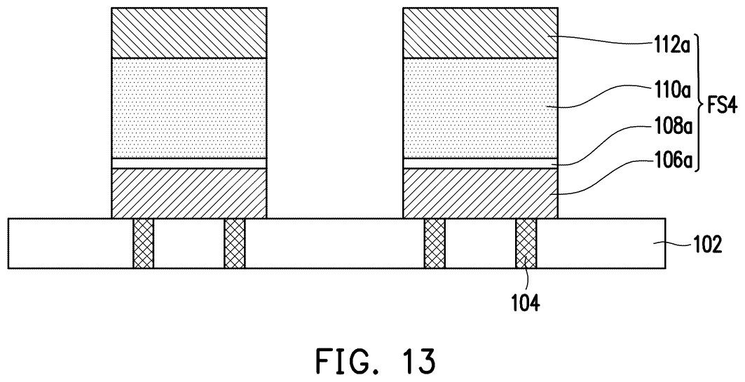

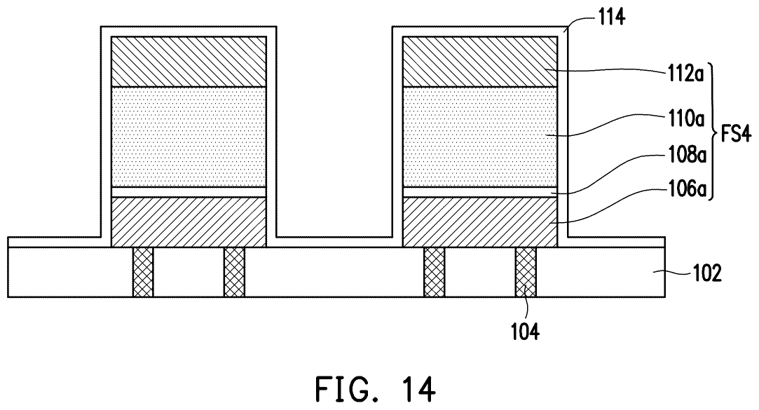

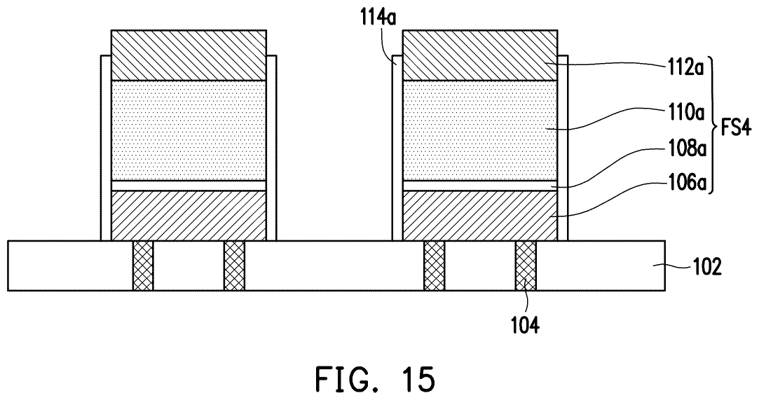

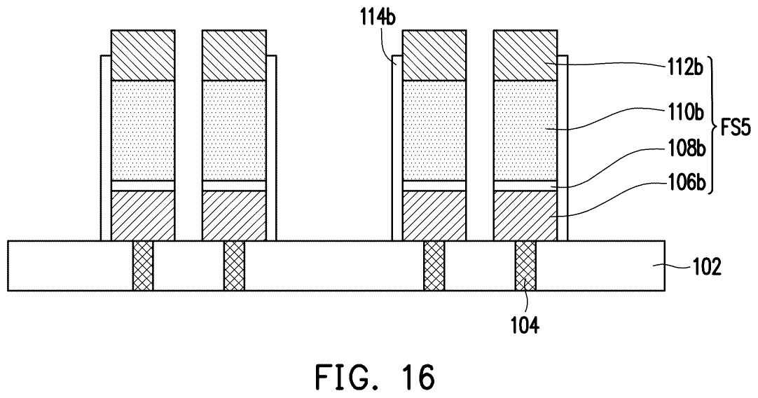

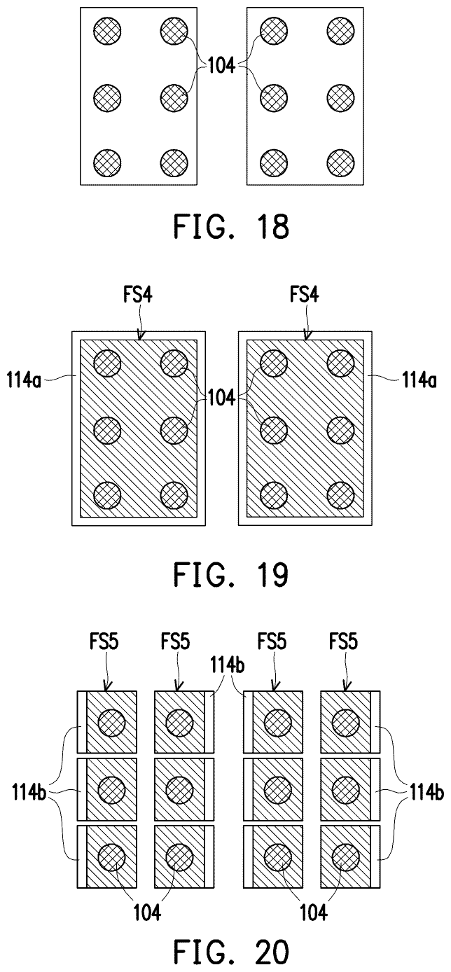

FIG. 12 through FIG. 17 schematically illustrate cross-sectional views of fabricating process of a memory cell in accordance with some other embodiments of the present disclosure. FIG. 18 schematically illustrates a top view of the film stacks illustrated in FIG. 13 in accordance with some embodiments of the present disclosure. FIG. 19 schematically illustrates a top view of the film stacks and the liner spacers illustrated in FIG. 15 in accordance with some embodiments of the present disclosure. FIG. 20 schematically illustrates a top view of the film stacks and the second liner portions illustrated in FIG. 16 in accordance with some embodiments of the present disclosure.

Referring to FIG. 1 through FIG. 4, FIG. 12 through FIG. 15, FIG. 18 as well as FIG. 19, the processes illustrated in FIG. 12 through FIG. 15 are similar to those illustrated in FIG. 1 through FIG. 4 except that the film stacks FS4 illustrated in FIG. 12 through FIG. 15 land on and are electrically connected to multiple conductive vias 104. For example, each one of the film stacks FS4 respectively covers and electrically connected to six underlying conductive vias 104, as illustrated in FIG. 18 and FIG. 19.

Referring to FIG. 15, FIG. 16 and FIG. 20, a patterning process (e.g., a photolithography process followed by an etch process) is performed to pattern the film stacks FS4 and the liner spacers 114a surrounding the film stacks FS4 such that film stacks FS5 and the second liner portions 114b covering one sidewall of the film stacks FS5 are formed. Three sidewalls of the film stacks FS5 are not covered by the second liner portions 114b. In other words, the film stacks FS4 and the liner spacers 114a are divided into the film stacks FS5 and the second liner portions 114b. As illustrated in FIG. 15, FIG. 16 and FIG. 20, the first electrode 106a, the first liner portion 108a, the storage element layer 110a and the second electrode 112a are further patterned by the above-mentioned patterning process such that each of the film stacks FS5 may respectively include a first electrode 106b, a first liner portion 108b on the first electrode 106b, a storage element layer 110b on the first liner portion 108b, and a second electrode 112b on the storage element layer 110b. The film stacks FS5 lands on the first dielectric layer 102 and are electrically connected to one of the underlying conductive vias 104. The film stacks FS5 are arranged in array and spaced apart from each other, as illustrated in FIG. 16.

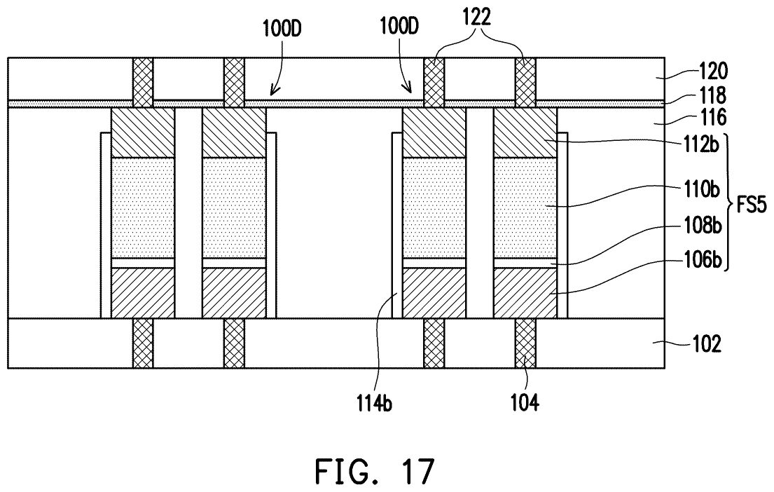

Referring to FIG. 17, the processes for fabricating memory cells 100D illustrated in FIG. 17 are similar to those illustrated in FIG. 6. Accordingly, the process detailed descriptions of the etch-stop layer 118, the dielectric layer 120 and the conductive vias 122 are omitted.

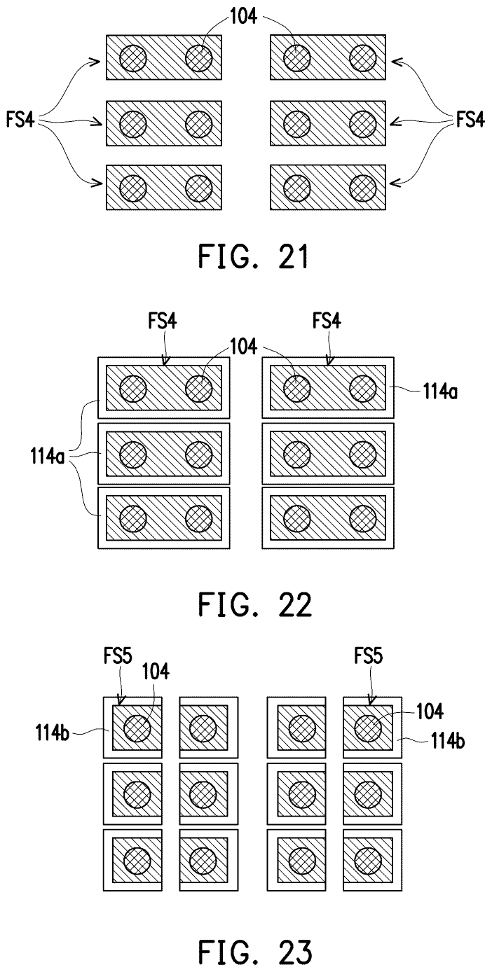

FIG. 21 schematically illustrates a top view of the memory cell illustrated in FIG. 13 in accordance with some alternative embodiments of the present disclosure. FIG. 22 schematically illustrates a top view of the memory cell illustrated in FIG. 15 in accordance with some alternative embodiments of the present disclosure. FIG. 23 schematically illustrates a top view of the memory cell illustrated in FIG. 16 in accordance with some alternative embodiments of the present disclosure.

Referring to FIG. 18 through FIG. 20 and FIG. 21 through FIG. 23, the processes illustrated in FIG. 21 through FIG. 23 are similar to those illustrated in FIG. 18 through FIG. 20 except that each one of the film stacks FS4 illustrated in FIG. 21 and FIG. 22 respectively covers and electrically connected to two underlying conductive vias 104. Furthermore, the second liner portions 114b cover three sidewalls of each one of the film stacks FS5, as illustrated in FIG. 23.

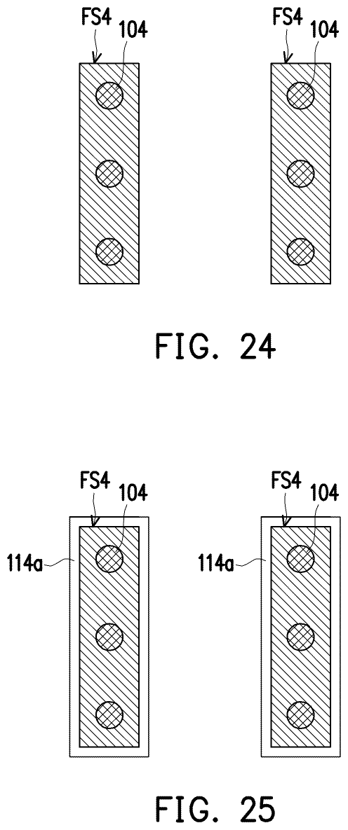

FIG. 24 through FIG. 26 schematically illustrates top views of the memory cell in accordance with some other embodiments of the present disclosure.

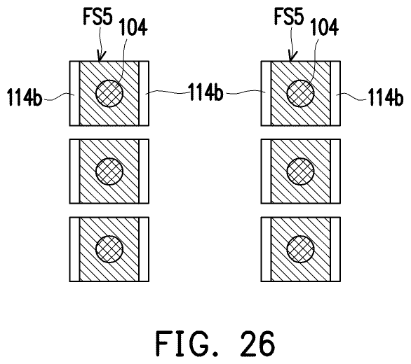

Referring to FIG. 18 through FIG. 20 and FIG. 24 through FIG. 26, the processes illustrated in FIG. 24 through FIG. 26 are similar to those illustrated in FIG. 18 through FIG. 20 except that each one of the film stacks FS4 illustrated in FIG. 24 and FIG. 25 respectively covers and electrically connected to three underlying conductive vias 104. Furthermore, the second liner portions 114b cover two opposite sidewalls of each one of the film stacks FS5, as illustrated in FIG. 26.

It is note that the above-mentioned memory cells 100, 100A, 100B, 100C and 100D can be integrated into interconnect structures of semiconductor dies. In other words, the fabrication processes of the above-mentioned embodiments can be integrated into and compatible with the Back-End-of-Line (BEOL) processes of the semiconductor wafers.

In the above-mentioned embodiments, since the liner layer including the first liner portion and the second liner portions dominates the overall resistivity of the memory cells, the resistance drift issue resulted from structure relaxation of the storage element layer (e.g., a phase change material) can be minimized, Furthermore, weight error in CIM computing resulted from the resistance drift issue can be avoided. Accordingly, reliability of PCM cells of the above-mentioned embodiments may be enhanced.

In accordance with some embodiments of the disclosure, a memory cell including a first electrode, a second electrode, a storage element layer and a liner layer is provided. The storage element layer is disposed between the first electrode and the second electrode. The liner layer covers the first electrode, the storage element layer and the second electrode, wherein a sidewall liner portion of the liner layer covers at least one sidewall of the first electrode, at least one sidewall of the storage element layer and at least one sidewall of the second electrode, and a third resistivity of the sidewall liner portion of the liner layer is greater than the first resistivity and less than the second resistivity.

In accordance with some embodiments of the disclosure, a memory cell including a first electrode, a second electrode, a phase change material and a liner layer is provided. The phase change material is disposed between the first electrode and the second electrode, wherein the phase change material switches between a low resistance state and a high resistance state, the phase change material has a first resistivity when the phase change material switches to the low resistance state, and the phase change material has a second resistivity when the phase change material switches to the high resistance state. The liner layer covers the first electrode, the storage element layer and the second electrode, wherein a first liner portion of the liner layer extends between the first electrode and the phase change material, and a third resistivity of the first liner portion of the liner layer is greater than the first resistivity and less than the second resistivity.

In accordance with some alternative embodiments of the disclosure, a method of forming a memory cell including following steps is provided. A first conductive layer, a first liner material layer on the first conductive layer, a storage element material layer on the first liner material layer, and a second conductive layer on the storage element material layer are formed. The first conductive layer, the first liner material layer, the storage element material layer and the second conductive layer are patterned to form a first film stack including a first electrode, a first liner portion on the first electrode, a storage element layer on the first liner portion, and a second electrode on the storage element layer. At least one second liner portion is formed on at least one sidewall of the first electrode, at least one sidewall of the storage element layer and at least one sidewall of the second electrode, wherein the at least one second liner portion is connected to the first liner portion.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A memory cell, comprising:
a first electrode;
a second electrode;
a storage element layer disposed between the first electrode and the second electrode;
a liner layer covering the first electrode, the storage element layer and the second electrode, wherein the liner layer comprises:
a first liner portion disposed between the first electrode and the storage element layer; and
at least one second liner portion covering at least one sidewall of the first electrode, at least one sidewall of the storage element layer and at least one sidewall of the second electrode, wherein the at least one second liner portion is connected to the first liner portion.

2. The memory cell according to claim 1, wherein the liner layer further comprises:
a third liner portion disposed between the second electrode and the storage element layer, wherein the at least one second liner portion is connected to the first liner portion and the third liner portion.

3. The memory cell according to claim 2, wherein the first liner portion and the third liner portion are disposed on opposite sides of the storage element layer.

4. The memory cell according to claim 1, wherein a height of the at least one second liner portion is greater than a thickness of the storage element layer.

5. The memory cell according to claim 1, wherein a height of the at least one second liner portion is greater than a sum of a first thickness of the storage element layer, a second thickness of the at least one second liner portion and a third thickness of the first electrode.

6. The memory cell according to claim 1, wherein the height of the at least one second liner portion is less than a sum of a first thickness of the storage element layer, a second thickness of the at least one second liner portion, a third thickness of the first electrode and a fourth thickness of the second electrode.

7. The memory cell according to claim 1, wherein the at least one second liner portion of the liner layer covers a single sidewall among sidewalls of the storage element layer.

8. The memory cell according to claim 1, wherein the at least one second liner portion of the liner layer covers two opposite sidewalls among sidewalls of the storage element layer.

9. The memory cell according to claim 1, wherein the at least one second liner portion of the liner layer covers three adjacent sidewalls among sidewalls of the storage element layer.

10. The memory cell according to claim 1, wherein the at least one second liner portion of the liner layer covers all sidewalls of the storage element layer.

11. A memory cell, comprising:
a first electrode;
a second electrode;
a phase change material disposed between the first electrode and the second electrode, wherein the phase change material switches between a low resistance state and a high resistance state, the phase change material has a first resistivity when the phase change material switches to the low resistance state, and the phase change material has a second resistivity when the phase change material switches to the high resistance state;
a liner layer covering the first electrode, the storage element layer and the second electrode, wherein a sidewall liner portion of the liner layer covers at least one sidewall of the first electrode, at least one sidewall of the storage element layer and at least one sidewall of the second electrode, and a third resistivity of the sidewall liner portion of the liner layer is greater than the first resistivity and less than the second resistivity.

12. The memory cell according to claim 11, wherein the liner layer further comprises a first liner portion disposed between the first electrode and the phase change material.

13. The memory cell according to claim 12, wherein the liner layer further comprises a second liner portion disposed between the second electrode and the storage element layer, wherein the sidewall liner portion is connected to the first liner portion and the second liner portion.

14. The memory cell according to claim 13, wherein the first liner portion and the second liner portion are disposed on opposite sides of the storage element layer.

15. A method of forming a memory cell, comprising:
forming a first conductive layer, a first liner material layer on the first conductive layer, a storage element material layer on the first liner material layer, and a second conductive layer on the storage element material layer;
patterning the first conductive layer, the first liner material layer, the storage element material layer and the second conductive layer to form a first film stack comprising a first electrode, a first liner portion on the first electrode, a storage element layer on the first liner portion, and a second electrode on the storage element layer; and
forming at least one second liner portion on at least one sidewall of the first electrode, at least one sidewall of the storage element layer and at least one sidewall of the second electrode, wherein the at least one second liner portion is connected to the first liner portion.

16. The method according to claim 15, wherein forming the at least one second liner portion comprises:
forming a second liner material layer covering the first film stack; and
removing a portion of the second liner material layer on a top surface of the first film stack to form the at least one second liner portion.

17. The method according to claim 16, wherein the second electrode is revealed after removing the portion of the second liner material layer on the top surface of the first film stack.

18. The method according to claim 15, wherein forming the at least one second liner portion comprises:
forming a second liner material layer covering the first film stack;
removing a portion of the second liner material layer on a top surface of the first film stack to form a liner spacer on sidewalls of the first film stack; and
patterning the first film stack and the liner spacer to form second film stacks and second liner portions, wherein each of the second liner portions covers at least two sidewalls of one of the second film stacks respectively.

19. The method according to claim 18, wherein the second electrode is revealed after removing the portion of the second liner material layer on the top surface of the first film stack.

20. The method according to claim 18, wherein patterning the first film stack and the liner spacer comprises:
removing portions of the first film stack to divide the first film stack into the second film stacks; and
removing portions of the liner spacer to divide the liner spacer into second liner portions such that the second liner portions remain on sidewalls of the second film stacks.
